(19) United States
(12) Patent Application Publication
(10) Pub. No.: US 2010/0199909 A1
(43) Pub. Date: Aug. 12, 2010

(54) SYSTEMS AND METHODS FOR RECYCLING SEMICONDUCTOR MATERIAL REMOVED FROM A RAW SEMICONDUCTOR BOULE

(75) Inventors: Eberhard Bamberg, Salt Lake City, UT (US); Dinesh R. Rakwal, Richfield, MN (US); Dean Jorgensen, Midvale, UT (US); Ian R. Harvey, Salt Lake City, UT (US); Michael L. Free, Salt Lake City, UT (US); Alagar K. Balaji, Salt Lake City, UT (US)

Correspondence Address: Ballard Spahr LLP, SUITE 1000, 999 PEACHTREE STREET, ATLANTA, GA, 30309-3915, US

(73) Assignee: University of Utah Research Foundation, Salt Lake City, UT (US)

(21) Appl. No.: 12/524,142

(22) PCT Filed: Jan. 25, 2008
(86) PCT No.: PCT/US08/52130

§ 371 Date: Apr. 15, 2010

Related U.S. Application Data
(60) Provisional application No. 60/886,645, filed on Jan. 25, 2007.

(51) Int. Cl. C30B 15/00; B23H 7/02; B23H 11/00

(52) U.S. Cl. 117/13; 117/208; 219/69.12; 219/69.17

(57) ABSTRACT

Methods of recycling excess semiconductor material removed from an unshaped semiconductor boule are disclosed. Excess semiconductor material is cut from an semiconductor unshaped boule thereby generating a shaped semiconductor boule. The excess semiconductor material is removed in the form of large pieces that can easily be cleaned and retrieved for reuse.

### GOVERNMENTAL INTERESTS

This invention was made with government support under Grant number NSF-0512897 awarded by the National Science Foundation. The United States government has certain rights to this invention.

### FIELD OF THE INVENTION

The invention relates generally to semiconductor manufacturing and more specifically to systems and methods for recycling excess semiconductor material removed from a raw semiconductor boule.

### BACKGROUND OF THE INVENTION

Semiconductor boule shaping is a manufacturing step that removes excess semiconductor material from a raw semiconductor ingot, or raw semiconductor boule to create a shaped semiconductor boule of a specified length and diameter. Abrasive prior art semiconductor boule shaping techniques, such as for example a creep grinding process, often remove the excess semiconductor material in the form of very small particles. The small particles may become contaminated with the grinding coolant and any released abrasives from the grinding tool. The resulting slurry can only be recycled with relatively great difficulty and as such is usually discarded as waste. Typically only high purity material (less than 1 ppm impurities) can be returned to the melt. In some cases, as much as 15% of a raw or unshaped semiconductor boule or excess semiconductor material is discarded as waste during the semiconductor boule shaping process. Semiconductor materials such as for example, including but not limited to, germanium and gallium-arsenide are relatively expensive materials. Therefore a relatively significant reduction in material costs may be realized if the excess semiconductor material removed during the semiconductor boule shaping can be recycled

### SUMMARY OF THE INVENTION

One aspect of the invention is directed to a method of recycling excess semiconductor material removed from an unshaped semiconductor boule. A wire electron discharge machine is provided. Excess semiconductor material is cut from an unshaped semiconductor boule using the wire electron discharge machine thereby generating a shaped semiconductor boule. The excess semiconductor material is in the form of large pieces and retrieved for reuse.

Another aspect of the invention is directed to a method of recycling excess semiconductor material removed from an unshaped semiconductor boule. The method includes providing a wire saw device, providing an unshaped semiconductor boule, cutting excess semiconductor material from the unshaped semiconductor boule using the wire saw thereby generating a shaped semiconductor boule, and retrieving the excess semiconductor material from the wire saw device for reuse.

Another aspect of the invention is directed to a system for recycling excess semiconductor material removed from an unshaped semiconductor boule. The system includes means for removing excess semiconductor material from an unshaped semiconductor boule in the form of large pieces thereby generating a shaped semiconductor boule, means for retrieving the excess semiconductor material is in the form of large pieces and means for reusing the retrieved excess semiconductor material in a melt.

### BRIEF DESCRIPTION OF THE DRAWINGS

FIG. 1 is a perspective view of one embodiment of a wire electron discharge machine (WEDM) that can be used to shape a raw semiconductor boule in a manner that enables the recycling of the semiconductor material removed from the raw semiconductor boule;

FIG. 2 is an illustration of an example of a pulse generator and control system that can be used with one embodiment of a WEDM;

FIG. 3 is an illustration of an example of a graphical user interface that can be used to control the operation of a WEDM;

FIG. 4 is an illustration of one example of a partially shaped germanium boule positioned in one embodiment of a WEDM; and

FIG. 5 is an illustration of a shaped germanium boule and the reusable excess semiconductor material that was removed from an unshaped germanium boule to create the shaped boule using one embodiment of a WEDM.

### DETAILED DESCRIPTION OF THE PREFERRED EMBODIMENTS

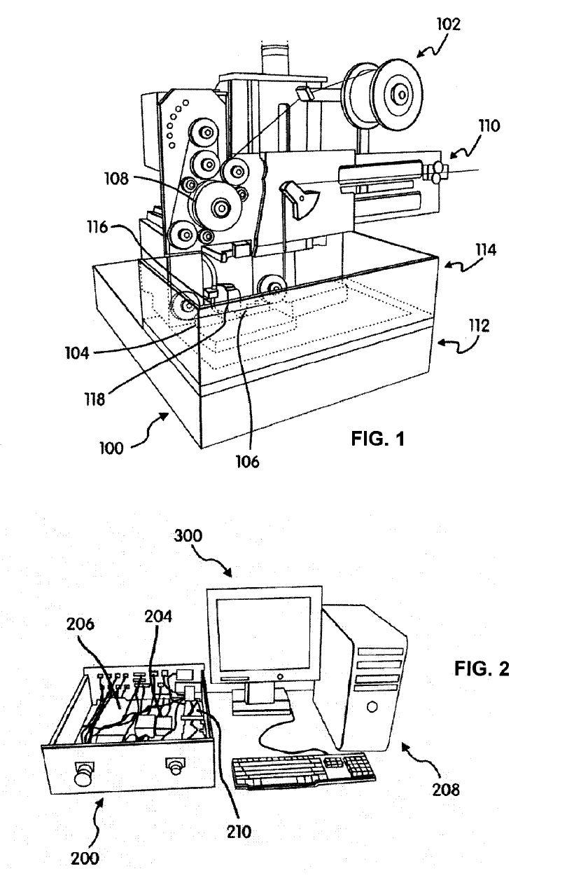

Referring to FIG. 1, an illustration of one embodiment of a wire electron discharge machine (WEDM) 100 that can be used to shape a raw semiconductor boule in a manner that enables the recycling of the semiconductor material removed from the raw semiconductor boule is shown. The WEDM 100 is used to a shape raw semiconductor boule by removing excess semiconductor material in a reusable form. In one embodiment, the WEDM 100 is used to shape a raw germanium boule. In one embodiment, the WEDM 100 is used to shape a raw silicon boule. In one embodiment, the WEDM 100 is used to shape a raw gallium arsenide boule. In one embodiment, the WEDM 100 is used to shape a raw indium phosphide boule. In one embodiment, the WEDM 100 allows for an overall work volume of approximately 300 mm by 150 mm by 250 mm.

In one embodiment, the WEDM 100 is used to cut the excess semiconductor material disposed at either end of a raw semiconductor boule, where the removed excess semiconductor material is in a reusable form. In one embodiment, the WEDM 100 is used to cut the excess semiconductor material from an outer diameter of a raw semiconductor boule to create a shaped semiconductor boule, where the removed excess semiconductor material is in a reusable form. In one embodiment, the WEDM 100 is used to cut excess semiconductor material to create a reference flat portion of a shaped semiconductor boule, where the removed excess semiconductor material is in a reusable form.

Using a WEDM 100 to shape a raw semiconductor boule allows the excess semiconductor material from the raw semiconductor boule to be removed in the form of relatively large reusable pieces. Removing large pieces of the excess semiconductor material using the WEDM 100 typically reduces the amount of subsurface damage to the shaped semiconductor boule. The removed large pieces of excess semiconductor are retrieved from the WEDM 100, and cleaned for reuse. The cleaned pieces of the excess semiconductor material are deposited into a melt used to create additional raw semiconductor boules. In one embodiment, additional raw semiconductor boules are created from the melt using the Czochralski process.

The WEDM 100 generally includes a wire supply spool 102, a left wire guide 104, a right wire guide 106, a wire brake 108, a wire puller 110, a machine base 112, a tank 114, and a dielectric fluid supply 116. In one embodiment, the left wire guide 104 is a fixed wire guide and the right wire guide 106 is an adjustable wire guide. In one embodiment, commercially available electron discharge machine (EDM) wire with diameters ranging from approximately 25 μm to approximately 250 μm is used. In one embodiment, the wire tension and wire speed are servo controlled. In one embodiment, the WEDM 100 includes four servo controlled axes. Two of the four servo controlled axes are used to control the wire speed and the wire tension. In one embodiment, the wire speed ranges from approximately 0 mm per second to approximately 250 mm per second. In one embodiment, the wire tension ranges from approximately 0.1 N to approximately 180 N. The other two of the four servo controlled axes are used to control the position of the wire in a vertical direction and in a horizontal direction where the vertical direction corresponds to the z-axis and the horizontal direction corresponds to the y-axis in a three dimensional x-y-z coordinate system. In one embodiment, the other two of the four axes are used to control the position of the wire in the vertical direction with a travel of approximately 150 mm and in the horizontal direction with a travel of approximately 100 mm. In one embodiment, the y-axis and the z-axis use optical linear encoders with a resolution of approximately 0.1 μm and an accuracy of better than approximately 1.0 μm per 100 mm. The wire is arranged horizontally and allows the spacing of the wire guides be varied from approximately 0 mm to approximately 250 mm. While one type of WEDM 100 has been described, alternative types and models of WEDMs can also be used. In an alternative embodiment, a wire saw is used to shape the raw semiconductor boule in a manner that enables the recycling of the semiconductor material removed from the raw semiconductor boule.

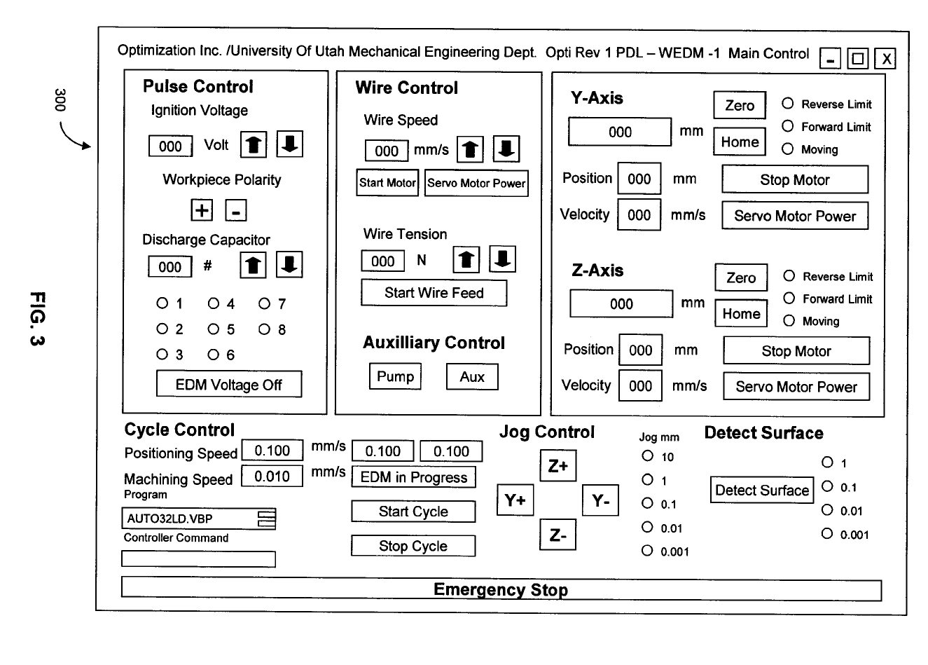

Referring to FIG. 2, an example of a pulse generator and control system 200 that can be used with one embodiment of a WEDM 100 is shown. In one embodiment, the WEDM 100 is powered and controlled by a modified Optimation Profile 24 control unit that includes a 4-axis PCI motion controller from Galil 202, an Optimation rev 5 pulse generator 204, and an Optimation opto-isolation board 206 that handles the input/output between the WEDM 100 and the controller 202. In one embodiment, the pulse generator and control system 200 is modified and interfaced with the WEDM 100 to provide the four servo controlled axes. Two of the four servo controlled axes are used to pull the EDM wire used to cut the raw semiconductor boule and to maintain a pre-defined wire tension. The other two of the four servo controlled axes are used to control the position of the wire in the vertical plane and the horizontal plane. The pulse generator and control system 200 also includes a host computer 208 and a servo amplifier 210.

In one embodiment, a pulse generator 204 designed for drilling small holes on the order of 10-200 microns is used. Since such pulse generators 204 are typically limited to a power output of approximately 300 W, the power output is increased by a factor of ten to approximately 3-5 kW thereby increasing the WEDM machining rate. In one embodiment a pulse generator 204 with a forced-discharge mode, as opposed to a self-discharge (RC) mode is used The use of such a pulse generator 204 provides the option of setting the pulse on and off times at selectable intervals, thereby resulting in increased control over the excess semiconductor material removal process. In one embodiment, more detailed control is provided over the energy discharges beyond selecting a voltage and the size of the capacitor. Alternative types and models of the pulse generators and/or control systems can also be used.

Referring to FIG. 3 an illustration of an example of a graphical user interface 300 that can be used to control the operation of one embodiment of a WEDM 100 is shown. The graphical user interface 300 is a component of Opti rev 1 control software. The WEDM 100 is controlled by Optimation's Opti rev 1 software and includes servo routines for the tensioning of the WEDM wire as well as servo routines for the vertical and horizontal axes that adapt the feed speed to the rate at which material is removed from the raw semiconductor boule during the boule shaping process. This prevents the WEDM wire from making physical contact with the work piece and results in a relatively better machining speed for a given set of WEDM parameters. While one example of a GUI and control software has been described, alternative types of GUIs and/or control software may be used.

In order to shape a raw unshaped semiconductor boule, the raw unshaped semiconductor boule is positioned in the WEDM 100. In one embodiment, the EDM wire is used to penetrate the top the raw semiconductor boule radially to a predefined depth. Next, using circular interpolation, the wire is moved in a circular trajectory to the bottom of the raw semiconductor boule thereby removing excess semiconductor material in a reusable form from a portion of the outer diameter of the raw semiconductor boule. The wire is then moved vertically down to exit the raw semiconductor boule. The partially shaped raw semiconductor boule is then rotated approximately 180 degrees to enable the machining of the remaining excess semiconductor material in a reusable form. While one technique for shaping a raw semiconductor boule using the WEDM 100 has been described alternative techniques may be used.

Surfaces that are machined using a WEDM 100 are often contaminated with residuals from the wire, dielectric fluid and some recast of the work piece material. The removed excess semiconductor material pieces are cleaned using an etchant. Examples of such etchants include, but are not limited to, nitric acid (HNO₃), acetic acid (CH₃COOH), hydrofluoric acid (HF), hydrogen peroxide (H₂O₂), sulfuric acid (H₂SO₄), and sodium hypochlorite (NaOCl). In one embodiment, the excess semiconductor pieces are cleaned using a solution of hydrofluoric acid (7 mol/l), acetic acid (6 mol/l), and nitric acid (6 mol/l). The cleaned excess semiconductor material pieces are returned to a melt that is used to grow raw semiconductor boules. Alternative cleaning solutions other than those described may be used to clean the removed excess semiconductor material so that the removed excess semiconductor material can be returned to a melt for reuse.

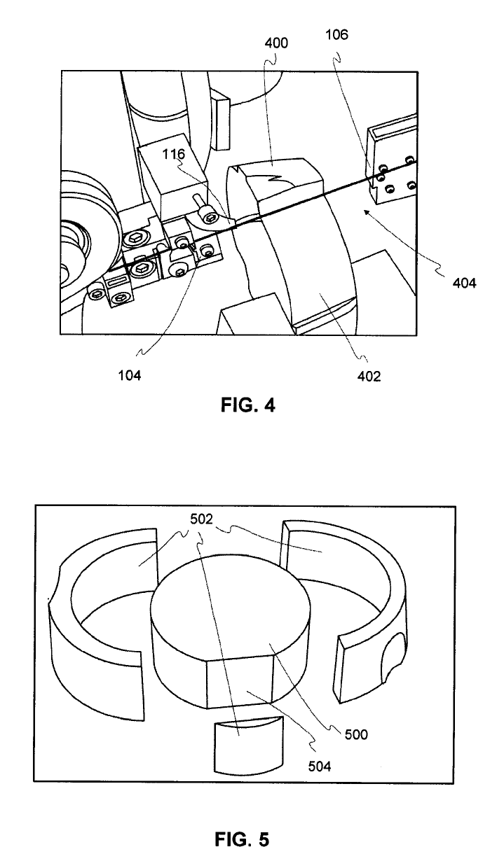

Referring to FIG. 4, an illustration of an example of a partially shaped germanium boule 400 positioned in one embodiment of a WEDM 100 with a finished side 402 and an EDM wire 404 is shown. The unshaped raw germanium boule 400 originally had an outer diameter that varied between approximately 81 mm and approximately 89 mm. A 200 micron diameter brass EDM wire, a spark voltage of 150 V, and a 68.8 nF capacitor with an associated discharge energy of 0.774 mJ were used. The wire was used to penetrate the top of the raw semiconductor boule radially to a depth of approximately 33 mm. Next, using circular interpolation, the wire was moved in a circular trajectory to the bottom of the raw germanium boule 400, thereby removing excess semiconductor material in a reusable form from a portion of the outer diameter of the raw germanium boule 400. The wire was then moved vertically down to exit the raw germanium boule 400. The partially shaped raw germanium boule 400 was then rotated 180 degrees to enable the machining of the remaining excess semiconductor material in a reusable form.

Referring to FIG. 5 an illustration of an example of a shaped germanium boule 500 having a referenced flat 504 and the excess semiconductor material 502 that was removed from the raw germanium boule in a reusable form using the WEDM 100 are shown. The total length of the WEDM cutting involved in removing of the excess semiconductor material from the raw germanium boule to create the shaped germanium boule 500 was approximately 230 mm. A slicing rate of approximately 3.1 mm²/min was used. This resulted in an effective machining rate of approximately 0.103 mm/min. The removal of the excess semiconductor material 502 from the raw germanium boule was completed in approximately 2150 minutes, or less than 36 hours. The excess semiconductor material removed from the raw semiconductor boule was in the form of two relatively large reusable pieces that were approximately 30 mm in thickness. The shaped semiconductor boule had an outer diameter of approximately 66 mm. A reference flat was machined using the WEDM 100. The excess semiconductor material removed from the raw semiconductor boule during the machining of the reference flat was in the form of a single reusable relatively large piece of semiconductor material. The removed relatively large pieces of the excess semiconductor material from the shaping of the outer diameter of the boule and the shaping of the reference flat were cleaned and returned to a melt for reuse.

In one embodiment, the WEDM 100 is designed based on a material specific set of determined machining parameters for shaping a raw semiconductor boule. In one embodiment, the WEDM 100 is designed based on a set of determined machining parameters for shaping a raw germanium boule. The set of machining parameters are identified based on a desired set of boule shaping parameters, including but not limited to, a desired slicing rate of the raw semiconductor boule, an acceptable surface roughness of a shaped semiconductor boule, and an acceptable amount of subsurface damage of the machined surfaces of the shaped semiconductor.

There is a relationship between the level of discharge energy and the slicing rate used to shape the raw semiconductor boule. There is also a relationship between the discharge energy and the amount of subsurface damage to the semiconductor boule shaped using the WEDM 100. More specifically, the discharge energy can be calculated using Equation (1)

$$E = \frac{1}{2} {CV}^{2} \qquad Equation ( 1 )$$

where E is the discharge energy measured in Joules, C is the capacitance measured in Farads, and V is the voltage measured in Volts. The slicing rate can be calculated using Equation (2)

$$S = \frac{L}{M} \qquad ( Equation ( 2 )$$

where S is the slicing rate measured in mm²/min, L is the length of cut measured in millimeters, and M is the machining rate measured in min/mm. These relationships are used to determine a threshold value of a level of discharge energy at which microcracks begin to appear in the semiconductor boules. The use of a level of discharge energy below the determined threshold value of the level of energy discharge typically significantly reduces or eliminates subsurface damage as a result of WEDM machining. By limiting the amount of discharge energy used in the machining process below the predetermined threshold limit, the WEDM 100 minimizes subsurface damage to the shaped semiconductor boule during the removing of the excess semiconductor material in a reusable form.

A relationship also exists between a size of the diameter of the wire used to cut the raw semiconductor boule and the slicing rate used to shape the raw semiconductor boule. Smaller or thinner wires typically machine or cut through a raw semiconductor boule at relatively faster slicing rates than thicker wires. Smaller wires, however, are typically more prone to breakage than thicker wires. To determine the effect of the wire size in cutting a raw semiconductor boule, the discharge energy density E_{d} is calculated using Equation (3):

$${E}_{d} = \frac{E}{π dL} \qquad Equation ( 3 )$$

where L is the length of cut and d is the diameter of the wire.

The slicing rate typically initially increases as the discharge energy is increased but then decreases eventually. A relatively smaller capacitor creates relatively smaller discharges at relatively higher frequencies while increasing the capacitance creates relatively bigger discharges at lower frequencies. Furthermore, there is a difference in slicing rate between different wire sizes at a given discharge energy. A smaller diameter wire typically achieves a relatively higher slicing rate, meaning that the excess semiconductor material can be cut away from a raw semiconductor boule at a relatively faster rate. For example, a 100 micron wire typically cuts up to approximately 86% faster than a 200 micron wire using the same discharge energy. In some cases, the severity of the subsurface damage at equal energy levels is reduced for smaller wires when compared to thicker wires.

In one embodiment, a method of recycling excess semiconductor material removed from an unshaped semiconductor boule includes providing a wire electron discharge machine, providing an unshaped semiconductor boule, cutting excess semiconductor material from the unshaped semiconductor boule using the wire electron discharge machine thereby generating a shaped semiconductor boule, and retrieving the excess semiconductor material from the wire electron discharge machine for reuse.

In one embodiment, the method includes cleaning the excess semiconductor material. In one embodiment, the retrieved excess semiconductor material was cleaned using an acid. Examples of such acids, include, but are not limited to hydrofluoric acid, acetic acid, nitric acid, hydrogen peroxide, sulfuric acid, or sodium hypochlorite.

In one embodiment the method includes adding the retrieved excess semiconductor material to a melt. In one embodiment, the method includes creating a raw or unshaped semiconductor boule from the melt. In one embodiment, the method includes creating a second unshaped or raw semiconductor boule from the melt using the Czochralski process.

In one embodiment, the method includes providing a first unshaped semiconductor boule selected from a group consisting of a germanium boule, a silicon boule, and gallium-arsenide boule, or indium phosphide boule. In one embodiment, the method includes cutting excess semiconductor material from an unshaped boule having an outer diameter ranging from approximately 105 millimeters to approximately 100 millimeters. In one embodiment, the method includes using a wire having a width ranging approximately 25 micrometers to approximately 250 micrometers. In one embodiment, the method includes cutting excess semiconductor material from an unshaped boule at a rate ranging from approximately 6 millimeters/hour to approximately 30 millimeters/hour. In one embodiment, the method includes retrieving excess semiconductor material ranging in weight from approximately 1.1 kg to approximately 11 kg.

In one embodiment, a method of recycling excess semiconductor material removed from an unshaped semiconductor boule includes providing a wire saw device, providing an unshaped semiconductor boule, cutting excess semiconductor material from the unshaped semiconductor boule using the wire saw thereby generating a shaped semiconductor boule, and retrieving the excess semiconductor material from the wire saw device for reuse.

In one embodiment, the method includes cleaning the excess semiconductor material. In one embodiment, the retrieved excess semiconductor material was cleaned using an acid. Examples of such acids, include, but are not limited to hydrofluoric acid, acetic acid, nitric acid, hydrogen peroxide, sulfuric acid, or sodium hypochlorite. In one embodiment the method includes adding the retrieved excess semiconductor material to a melt. In one embodiment, the method includes creating a raw or unshaped semiconductor boule from the melt. In one embodiment, the method includes creating a second unshaped or raw semiconductor boule from the melt using the Czochralski process. In one embodiment, the method includes providing a first unshaped semiconductor boule selected from a group consisting of a germanium boule, a silicon boule, and gallium-arsenide boule, or indium phosphide boule.

In one embodiment, a system for recycles excess semiconductor material removed from an unshaped semiconductor boule. The system includes means for removing excess semiconductor material from an unshaped semiconductor boule in the form of large pieces thereby generating a shaped semiconductor boule, means for retrieving the excess semiconductor material is in the form of large pieces and means for reusing the retrieved excess semiconductor material in a melt.

In one embodiment, the system includes means for cleaning the excess semiconductor material. In one embodiment, the retrieved excess semiconductor material is cleaned using an acid. Examples of such acids, include, but are not limited to hydrofluoric acid, acetic acid, nitric acid, hydrogen peroxide, sulfuric acid, or sodium hypochlorite. In one embodiment the system includes means for adding the retrieved excess semiconductor material to a melt. In one embodiment, the system includes means for creating a raw or unshaped semiconductor boule from the melt. In one embodiment, the system includes means for creating a second unshaped or raw semiconductor boule from the melt using the Czochralski process. In one embodiment, the system includes means for providing a first unshaped semiconductor boule selected from a group consisting of a germanium boule, a silicon boule, and gallium-arsenide boule, or indium phosphide boule.

While the embodiments of the invention disclosed herein are presently considered to be preferred, various changes, and modifications can be made without departing from the spirit and scope of the invention. The scope of the invention is indicated in the appended claims, and all changes that come within the meaning and range of equivalents are intended to be embraced therein.

1. A method of recycling excess semiconductor material removed from an unshaped semiconductor boule, the method comprising:
providing a wire electron discharge machine;
providing an unshaped semiconductor boule;
cutting excess semiconductor material from the unshaped semiconductor boule using the wire electron discharge machine thereby generating a shaped semiconductor boule; and
retrieving the excess semiconductor material from the wire electron discharge machine for reuse.

2. The method of claim 1, further comprising cleaning the retrieved excess semiconductor material.

3. The method of claim 2, wherein cleaning the retrieved excess semiconductor material comprises cleaning the retrieved excess semiconductor material using an acid selected from a group consisting of hydrofluoric acid, acetic acid, nitric acid, hydrogen peroxide, sulfuric acid, and sodium hypochlorite.

4. The method of claim 1, further comprising adding the retrieved excess semiconductor material to a melt.

5. The method of claim 4, further comprising creating a second unshaped semiconductor boule from the melt.

6. The method of claim 4, further comprising creating a second unshaped semiconductor boule from the melt using the Czochralski process.

7. The method of claim 1, wherein providing a first unshaped semiconductor boule comprises providing a first unshaped semiconductor boule selected from a group consisting of a germanium boule, a silicon boule, gallium-arsenide boule and indium phosphide boule.

8. The method of claim 1, wherein cutting excess semiconductor material from an unshaped boule using the wire electron discharge machine thereby generating a shaped semiconductor boule comprises cutting excess semiconductor material from an unshaped boule having an outer diameter ranging from approximately 105 millimeters to approximately 100 millimeters.

9. The method of claim 1, wherein cutting excess semiconductor material from an unshaped boule using the wire electron discharge machine thereby generating a shaped semiconductor boule comprises using a wire having a width ranging approximately 25 micrometers to approximately 250 micrometers.

10. The method of claim 1, wherein cutting excess semiconductor material from an unshaped boule using the wire electron discharge machine thereby generating a shaped semiconductor boule comprises, cutting excess semiconductor material from an unshaped boule at a rate ranging from approximately 6 millimeters/hour to approximately 30 millimeters/hour.

11. The method of claim 1, wherein retrieving the excess semiconductor material for reuse comprises retrieving excess semiconductor material ranging in weight from approximately 1.1 kg to approximately 11 kg.

12. A method of recycling excess semiconductor material removed from an unshaped semiconductor boule, the method comprising:
providing a wire saw device;
providing an unshaped semiconductor boule;
cutting excess semiconductor material from the unshaped semiconductor boule using the wire saw thereby generating a shaped semiconductor boule; and
retrieving the excess semiconductor material from the wire saw device for reuse.

13. The method of claim 12, further comprising cleaning the retrieved excess semiconductor material.

14. The method of claim 13, wherein cleaning the retrieved excess semiconductor material comprises cleaning the retrieved excess semiconductor material using an acid selected from a group consisting of hydrofluoric acid, acetic acid, nitric acid, hydrogen peroxide, sulfuric acid, and sodium hypochlorite.

15. The method of claim 12, further comprising adding the retrieved excess semiconductor material to a melt.

16. The method of claim 15, further comprising creating a second unshaped semiconductor boule from the melt.

17. The method of claim 15, further comprising creating a second unshaped semiconductor boule from the melt using the Czochralski process.

18. The method of claim 12, wherein providing a first unshaped semiconductor boule comprises providing a first unshaped semiconductor boule selected from a group consisting of a germanium boule, a silicon boule, gallium-arsenide boule and indium phosphide boule.

19. A system for recycling excess semiconductor material removed from an unshaped semiconductor boule comprising:
means for removing excess semiconductor material from an unshaped semiconductor boule in the form of large pieces thereby generating a shaped semiconductor boule,
means for retrieving the excess semiconductor material is in the form of large pieces; and
means for reusing the retrieved excess semiconductor material in a melt.

20. The system of claim 19, further comprising means for cleaning the retrieved excess semiconductor material.

21. The system of claim 19, wherein the means for cleaning the retrieved excess semiconductor material comprises means for cleaning the retrieved excess semiconductor material using an acid selected from a group consisting of hydrofluoric acid, acetic acid, nitric acid, hydrogen peroxide, sulfuric acid, and sodium hypochlorite.

22. The system of claim 19, further comprising means for adding the retrieved excess semiconductor material to a melt.

23. The system of claim 22, further comprising means for creating a second unshaped semiconductor boule from the melt.

24. The system of claim 22, further comprising means for creating a second unshaped semiconductor boule from the melt using the Czochralski process.

25. The system of claim 19, wherein means for providing a first unshaped semiconductor boule comprises means for providing a first unshaped semiconductor boule selected from a group consisting of a germanium boule, a silicon boule, gallium-arsenide boule and indium phosphide boule.
